(19) United States
(12) Patent Application Publication
(10) Pub. No.: US 2025/0374477 A1
(43) Pub. Date: Dec. 4, 2025

(54) COOLER ASSEMBLIES FOR FLUID EDGE COOLING

(71) Applicant: Toyota Motor Engineering & Manufacturing North America, Inc., Plano, TX (US)

(72) Inventors: Yuqing Zhou, Ann Arbor, MI (US); Ercan M. Dede, Ann Arbor, MI (US); Paul D. Schmalenberg, Ann Arbor, MI (US); Utsav Raj Aryal, Ypsilanti, MI (US); Gaohua Zhu, Ann Arbor, MI (US)

(73) Assignees: Toyota Motor Engineering & Manufacturing North America, Inc., Plano, TX (US); Toyota Jidosha Kabushiki Kaisha, Toyota-shi, Aichi-ken (JP)

(21) Appl. No.: 18/677,004

(22) Filed: May 29, 2024

(51) Int. Cl. H05K 7/20

(52) U.S. Cl. CPC H05K 7/20254

(57) ABSTRACT

Embodiments herein are directed to a cooler assembly. The cooler assembly includes a base plate, a macro-channel plate, and an insert plate. The base plate has a first surface opposite second surface. The macro-channel plate has a corrugated portion defined by a plurality of alternating ridges and valleys extending in a first direction. Each of the plurality of alternating ridges have an elongated slot fluidly coupling the macro-channel plate to the base plate. The insert plate has an inner surface and opposite outer surface. The inner surface abutting the plurality of alternating ridges. The insert plate has a plurality of alternating raised channel portions and recesses. Each of the plurality of recesses has an elongated passage fluidly coupling the insert plate to the macro-channel plate. Each of the plurality of alternating raised channel portions and recesses extending in a second direction that is perpendicular to the first direction.

### TECHNICAL FIELD

The present specification generally relates to cooler assemblies and, more particularly, to cooler assemblies utilizing stamped cold plates.

### BACKGROUND

Heat management devices may be coupled to a heat generation device, such as a power electronics device or integrated circuit (e.g., central processing unit, CPU, or graphics processing unit, GPU), to remove heat and lower the operating temperature of the heat-generating device. A liquid coolant, such as a cooling fluid, may be introduced to the heat management device, where it receives heat from the heat management device, primarily through convective and/or conductive heat transfer. One such example is a manifold microchannel cold plate. Conventional manifold microchannel cold plates are popular for cooling electronics components with rather small footprint dimensions (centimeter scale). However, the components have complex geometries, which hinder economical mass production. Further, the overall cold plate packaging size is also bulky relative to the heat generation devices to be cooled. As such, a need exists for low-cost mass production cooling solutions for applications with large cooling area requirements, (e.g., electric vehicle batteries and fuel cell stacks).

### SUMMARY

In one aspect, a cooler assembly is provided. The cooler assembly includes a base plate, a macro-channel plate, and an insert plate. The base plate has a first surface opposite a second surface. The macro-channel plate has a corrugated portion defined by a plurality of alternating ridges and valleys. Each of the plurality of alternating ridges and valleys extending in a first direction. Each of the plurality of alternating ridges have an elongated slot fluidly coupling the macro-channel plate to the base plate. The insert plate has an inner surface and opposite outer surface. The inner surface abutting the plurality of alternating ridges of the macro-channel plate. The insert plate has a plurality of alternating raised channel portions and recesses. Each of the plurality of recesses has an elongated passage fluidly coupling the insert plate to the macro-channel plate. Each of the plurality of alternating raised channel portions and recesses extending in a second direction that is perpendicular to the first direction.

In another aspect, an electronics assembly is provided. The electronics assembly includes a heat-generating device and a cooler assembly thermally coupled to the heat-generating device. The cooling assembly includes a base plate, a macro-channel plate, an insert plate, and a cover plate. The base plate has a first surface opposite second surface. The macro-channel plate has a corrugated portion defined by a plurality of alternating ridges and valleys extending in a first direction. Each of the plurality of alternating ridges have an elongated slot fluidly coupling the macro-channel plate to the base plate. The insert plate has an inner surface opposite outer surface. The inner surface abutting the plurality of alternating ridges of the macro-channel plate. The insert plate has a plurality of alternating raised channel portions and recesses. Each of the plurality of recesses have an elongated passage fluidly coupling the insert plate to the macro-channel plate. Each of the plurality of alternating raised channel portions and recesses extending in a second direction that is perpendicular to the first direction. The cover plate has an interior surface with a cavity portion configured to receive the macro-channel plate and the insert plate. Portions of the interior surface abutting the first surface of the base plate. The heat-generating device is coupled to the second surface of the base plate.

In yet another aspect, a method for forming a cooler assembly is provided. The method includes forming a base plate having a first surface and an opposite second surface defining a thickness, forming a macro-channel plate having a plurality of alternating ridges and a plurality of alternating valleys extending in a first direction, each of the plurality of alternating ridges having an elongated slot configured to fluidly couple the macro-channel plate to the first surface of the base plate, forming an insert plate having a plurality of alternating raised channel portions and a plurality of alternating recesses, each of the plurality of alternating raised channel portions and each of the plurality of alternating recesses extending in a second direction, the second direction is perpendicular to the first direction, each of the plurality of alternating recesses having an elongated passage configured to fluidly couple the insert plate to the macro-channel plate, and forming a cover plate having a cavity portion configured to receive the insert plate and the macro-channel plate, portions of the cover plate is configured to abut with the first surface of the base plate in an assembled state such that the cooler assembly is in a vertically stacked arrangement.

These and additional objects and advantages provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of an example cooler assembly according to one or more embodiments shown or described herein;

FIG. 2 schematically depicts a perspective exploded view of the cooler assembly of FIG. 1 according to one or more embodiments shown or described herein;

FIG. 3 schematically depicts a perspective view of the example cooler assembly of FIG. 1 further illustrating a liquid coolant flow according to one or more embodiments shown or described herein;

FIG. 4A schematically depicts a perspective view of a plurality of example cooler assemblies of FIG. 1 in a stacked arrangement according to one or more embodiments shown or described herein;

FIG. 4B schematically depicts a perspective isolated view of a portion of the plurality of example cooler assemblies of FIG. 4A according to one or more embodiments shown or described herein;

FIG. 5 schematically depicts a front plan view of the plurality of example cooler assemblies of FIG. 4A according to one or more embodiments shown or described herein;

FIG. 6 schematically depicts a cross sectional front plan view of the plurality of example cooler assemblies of FIG. 4A, further illustrating insulating layers between the example cooler assemblies according to one or more embodiments shown or described herein;

FIG. 7A schematically depicts a perspective view of a unit cell of the example cooler assembly of FIG. 1 according to one or more embodiments shown or described herein;

FIG. 7B schematically depicts a conjugate heat transfer analysis of the unit cell of FIG. 7A according to one or more embodiments shown or described herein;

FIG. 8 schematically depicts a perspective exploded view of a second aspect of the cooler assembly of FIG. 1 according to one or more embodiments shown or described herein; and

FIG. 9 depicts a flow diagram of an illustrative method for forming the example cooler assembly of FIG. 1 according to one or more embodiments shown and described herein.

### DETAILED DESCRIPTION

Embodiments of the present disclosure are directed to a cooler assembly for thermal management of heat-generating devices, such as CPU or GPU devices found in data centers, or power electronics devices found in vehicle energy conversion applications. Current trends require heat removal from devices with larger cooling implementations, such as those associated with hydrogen fuel cells and electric vehicle batteries. The cooler assembly disclosed herein provides a low-cost cold plate assembly that includes four plates stacked in a vertical direction and in which each plate is formed from sheet metal. Specifically, embodiments of the present disclosure provide the following advantages from conventional cooler assemblies: 1.) reduce the cold plate packaging volume by utilizing innovative stacking configurations made of thin sheet metal components; 2.) reduce the cost by utilizing sheet metal forming for major components, which is suitable for economical mass production; and 3.) provide a solution for applications with large cooling area requirements, e.g., EV batteries and FC stacks.

As described in more detail herein, the cooler assembly includes four independent stamped sheet metal plates. A heat source is coupled to a bottom surface of a base plate. Another stamped plate is a stamped macro-channel plate, which is positioned above the base plate in a vertical direction and includes a corrugated surface defined by a plurality of alternating ridges and valleys. Each of the plurality of alternating ridges and valleys extend in a first direction. A third stamped plate is an insert plate, which has an inner surface and opposite outer surface. The inner surface is configured to abut the plurality of alternating ridges of the macro-channel plate. The insert plate also includes a plurality of alternating raised channels portions and recesses. Each of the plurality of recesses have an elongated slot to fluidly couple the insert plate to the macro-channel plate. Each of the plurality of alternating raised channels portions and recesses extend in a second direction, which is perpendicular to the first direction. Further, the last stamped plate is a cover plate that includes an interior surface with a recess portion configured to receive and enclose the macro-channel plate and the insert plate. The interior surface is configured to abut the first surface of the base plate such that the cooler assembly is in a vertically stacked arrangement in a vertical direction and to seal a liquid coolant inside the cold plate assembly.

Each of the plates may be stamped using thin metal, such as sheet metal (e.g., aluminum, steel, alloys and the like, generally having a thickness between 0.5 mm and 6.0 mm), driving low manufacturing costs, easily shapeable, scalable, and the like.

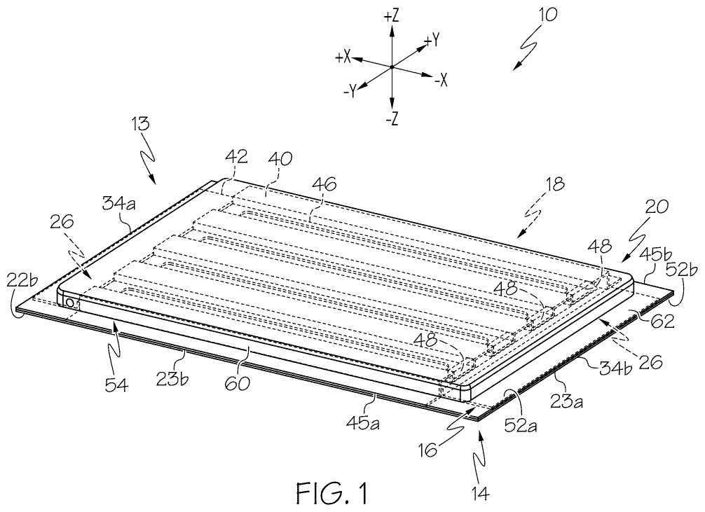

As used herein, the term “longitudinal direction” refers to the forward-rearward direction of the cooler assembly (e.g., in the +/−X-direction depicted in FIG. 1). The term “lateral direction” refers to the cross cooler assembly direction (e.g., in the +/−Y-direction depicted in FIG. 1), and is transverse to the longitudinal direction. The term “vertical direction” or “up” or “above” or “below” refer to the upward-downward direction of the cooler assembly (e.g., in the +/−Z-direction depicted in FIG. 1).

Turning now to the figures, FIGS. 1-3 illustrate various schematic depictions of an example cooler assembly 10. The example cooler assembly 10 may be configured to remove, for example, a heat flux of a heat-generating device 12 that is coupled to the example cooler assembly 10, as discussed in greater detail herein.

The heat-generating device 12 may be a central processing unit (CPU) or a graphics-processing unit (GPU) that use integrated circuits and are commonly found and associated with data centers. Further, the heat-generating device 12 may be a power device that may include one or more semiconductor devices such as, but not limited to, an insulated gate bipolar transistor (IGBT), a reverse conducting IGBT (RC-IGBT), a metal-oxide-semiconductor field-effect transistor (MOSFET), a power MOSFET, a diode, a transistor, and/or combinations thereof. In some embodiments, the heat-generating device 12 may include a wide-bandgap semiconductor, and may be formed from any suitable material such as, but not limited to, silicon carbide (SiC), silicon dioxide (SiO₂), aluminum nitride (AlN), gallium nitride (GaN), and boron nitride (BN), and the like. In some embodiments, the heat-generating device 12 may include ultra-wide-bandgap devices formed from suitable materials such as AlGaN/AlN, Ga₂O₃, and diamond. In some embodiments, the heat-generating device 12 may operate within a power module having a high current and/or a high power and under high temperatures (for example, in excess of 100° C., 150° C., 175° C., 200° C., 225° C., or 250° C.) and dissipate a large amount of power in the form of heat that is removed for the continued operation of the heat-generating device 12. In other embodiments, the heat-generating device 12 provides a cooling solution for applications with large cooling area requirements, such as, without limitation, electric vehicle batteries and fuel cell stacks.

Accordingly, the heat-generating device 12 may be suitable in vehicle power electronics, in data center applications with integrated circuits, and the like. The heat generated by the heat-generating device 12 may be conducted away via the cooler assembly 10 to cool the heat-generating device 12. Further, the heat-generating device 12 may be any shape or size. Further, the heat-generating device 12 may include a base surface 15a and an opposite contact surface 15b.

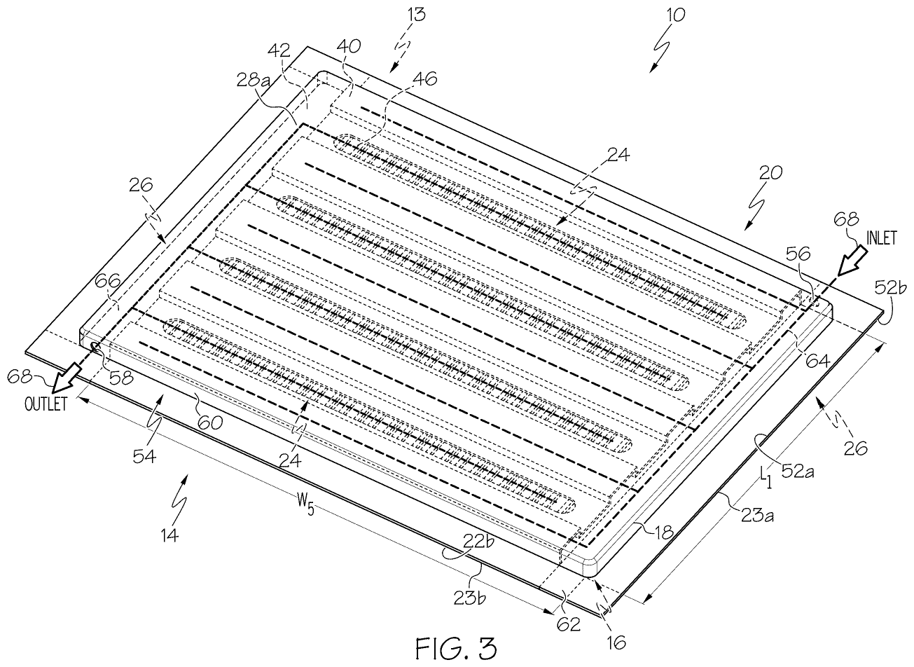

The example cooler assembly 10 may include a cold plate assembly 13 that includes a base plate 14, a macro-channel plate 16, an insert plate 18, and a cover plate 20. The cover plate 20 may act as a cover to enclose portions of the base plate 14, macro-channel plate 16 and insert plate 18, to seal a liquid coolant 68 (FIG. 3) therein, as discussed in greater detail herein. Non-limiting example liquid coolants include dielectric cooling fluids such as deionized water, R-245fa, and HFE-7100. Other dielectric cooling fluids may be utilized. The type of dielectric cooling fluid chosen may depend on the operating temperature of the heat-generating devices to be cooled.

The base plate 14 may include a cover receiving surface 22a and an opposite device receiving surface 22b. The cover receiving surface 22a may be in contact with, or abut, portions of the cover plate 20. That is, the cover receiving surface 22a may be planar and provide a mounting or coupling surface for the portions of the cover plate 20 to rest on, abut, bond onto, and the like, as discussed in greater detail herein.

In the depicted embodiment, the base plate 14 is generally depicted in a generally rectangular shape and is dimensionally larger than the heat-generating device 12 with a pair of ends 23a and a pair of edges 23b in which the pair of edges 23b extend a greater distance than the pair of ends 23a. This is non-limiting and the base plate 14 may be dimensionally sized to match or be equal to the size of the heat-generating device 12. In other embodiments, the base plate 14 may be dimensionally sized to be smaller than the size of the heat-generating device 12. The size and shape of the base plate 14 is non-limiting and the base plate 14 may be any size and shape, including, without limitation, square, hexagonal, octagonal, circular, triangular, and/or the like. As such, the base plate 14 may be any shape, size, and/or dimension.

It should be appreciated that the base plate 14 may be formed by sheet metal forming. In other embodiments, the base plate 14 may be formed by etching a silicon wafer or by micromachining a Cu substrate. As such, in some embodiments, the base plate 14 may be a silicon material. In other embodiments, the base plate 14 may be Cu, AlSiC, or other materials. Further, a thickness of the base plate 14 may depend on the intended use of the example cooler assembly 10 and limitations of the sheet metal forming. That is, the thickness may vary depending on whether the heat-generating device 12 is an integrated circuit CPU/GPU, a power electronic semiconductor, an EV battery or fuel cell stack, and the like, of an electronics assembly. As such, the illustrated embodiments and present disclosure are non-limiting as the thickness of the base plate 14 varies based on application and sheet metal forming capabilities.

In some embodiments, the contact surface 15b of the heat-generating device 12 may be thermally coupled to or otherwise thermally attached to portions of the device receiving surface 22b. That is, in some embodiments, the contact surface 15b of the heat-generating device 12 may be bonded to portions of the device receiving surface 22b of the base plate 14 via a thermal interface layer. The thermal interface layer may include a thermally conductive bond and may include a DBC (direct bonded copper) substrate, solder, or some other high temperature substrate, bonding material, or method. In other embodiments, the thermal interface layer may be a thermal grease positioned between the device receiving surface 22b of the base plate 14 and heat-generating device 12.

Still referring to FIGS. 1-3, the macro-channel plate 16 includes a corrugated portion 24 and a pair of planar tab portions 26 on either side of the corrugated portion 24 depicted in the longitudinal direction (e.g., in the +/−X direction) to define a first end 34a and an opposite second end 34b. The macro-channel plate 16 includes a corrugated surface 28a and an opposite coupling surface 28b spaced apart from the corrugated surface 28a to define a thickness. In some embodiments, the thickness may be 0.8 mm. It should be understood that this is non-limiting and the thickness may be thinner than 0.8 mm limited only by the material used and the stamping process as appreciated by those with skill in the art, or may be thicker than the 0.8 mm.

The coupling surface 28b of the macro-channel plate 16 faces the cover receiving surface 22a of the base plate 14 such that in an assembled state, the coupling surface 28b of the macro-channel plate 16 abuts with the cover receiving surface 22a of the base plate 14. The corrugated portion 24 defined by a plurality of alternating ridges 30 and a plurality of alternating valleys 32 extending between the pair of planar tab portions 26, and between a first edge 35a and an opposite second edge 35b. The corrugated surface 28a and the coupling surface 28b follow the contour of the plurality of alternating ridges 30 and the plurality of alternating valleys 32 as well as the pair of planar tab portions 26. Each of the plurality of alternating ridges 30 and the plurality of alternating valleys 32 extend in a first direction, depicted by arrow A1. The first direction is generally in the lateral direction (e.g., in the +/−Y direction) extending between the first edge 35a and the second edge 35b.

Portions of the coupling surface 28b (e.g., at each of the plurality of alternating valleys 32) may be configured to be generally planar in shape to abut the cover receiving surface 22a of the base plate 14. As such, portions of the coupling surface 28b alternate to varying heights in the vertical direction (e.g., in the +/−Z direction) to follow the contour of the plurality of alternating ridges 30 and the plurality of alternating valleys 32 of the corrugated portion 24. Further, portions of the coupling surface 28b (e.g., at the pair of planar tab portions 26) may be configured to planar in shape to abut the cover receiving surface 22a of the base plate 14 with a greater surface area than those of each of the coupling surface 28b at the plurality of alternating valleys 32.

In the depicted embodiment, each of the plurality of alternating valleys 32 have a width W1, which is uniform in size and shape to define each of the plurality of alternating valleys 32. Additionally, each of the plurality of alternating ridges 30 have a width W2 and a height H1 with reference to the corrugated surface 28a of the pair of planar tab portions 26, which are each uniform in size and shape to define each of the plurality of alternating ridges 30. This is non-limiting and each or some of the widths W1 of the plurality of alternating valleys 32 may be irregular or non-uniform width. Further, either independently or in combination with the non-uniform width of the plurality of alternating valleys 32, each width W2 and/or height H1 of the plurality of alternating ridges 30 may be irregular or non-uniform, dependent on the type of heat-generating device 12, cooling parameters and desires, and the like, as appreciated by those having skill in the art.

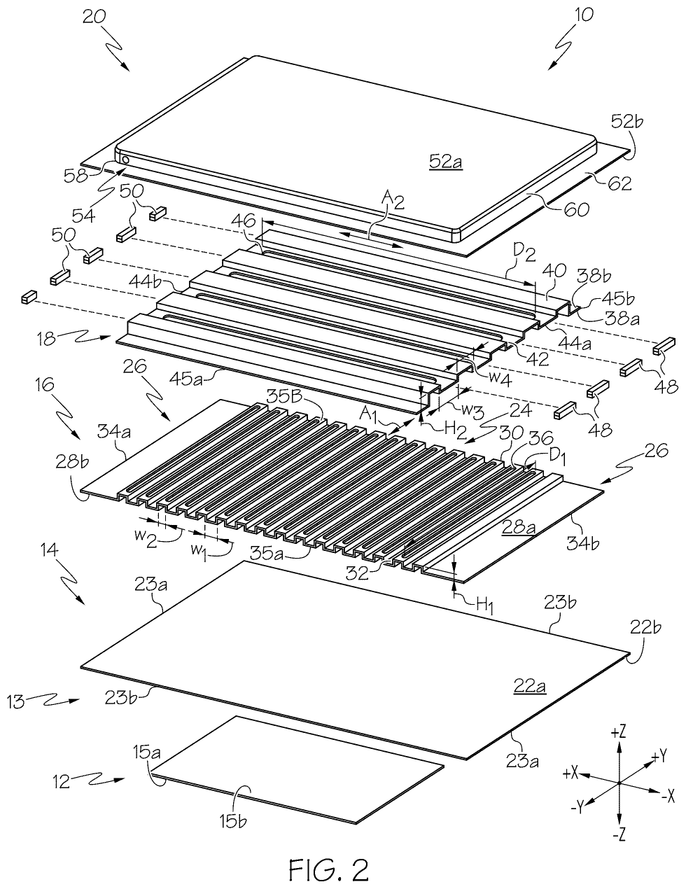

In some embodiments, as best depicted in FIG. 2, the width W1 of each of the plurality of alternating valleys 32 may be equal to the width W2 of each of the plurality of alternating ridges 30. In a non-limiting example, the width W1 and the width W2 are each 8.4 mm. It should be appreciated that this is merely an example and the width W1 and the width W2 may be less than or greater than 8.4 mm. In some embodiments, the width W1 and/or the width W2 may be greater than the height H1 of the plurality of alternating ridges 30. In a non-limiting example, the height H1 may be 5.2 mm. It should be appreciated that this is merely an example and the height H1 may be less than or greater than 5.2 mm.

In other embodiments, the width W1 of each of the plurality of alternating valleys 32 may greater than, or extend a larger distance, than the width W2 of each of the plurality of alternating ridges 30. In other embodiments, the width W1 of each of the plurality of alternating valleys 32 may be smaller, or extend a smaller distance, than the width W2 of each of the plurality of alternating ridges 30. Further, in other embodiments, the width W1 of one or some of the plurality of alternating valleys 32 may be larger, or extend a greater distance, than the width W2 of one or some of the plurality of alternating ridges 30. In other embodiments, the width W1 of one or some of the plurality of alternating valleys 32 may be equal to or smaller than the width W2 of one or some of the plurality of alternating ridges 30.

In the depicted embodiment, each of the plurality of alternating ridges 30 include an elongated slot 36 extending in the same direction as the plurality of alternating ridges 30. In the depicted embodiment, each elongated slot 36 of the plurality of alternating ridges 30 extends between the first end 34a and the second end 34b in the lateral direction (e.g., in the +/−Y direction) and extends a uniform distance D1 or length to be sized and shaped in a uniform geometry. In a non-limiting example, each elongated slot 36 of the plurality of alternating ridges 30 may have a width or opening of 5 mm. It should be understood that this is non-limiting and each elongated slot 36 of the plurality of alternating ridges 30 may have a width or opening greater than or less than 5 mm.

In other embodiments, the elongated slot 36 of each of the plurality of alternating ridges 30 may extend different distances or lengths, or be sized and/or shaped differently. In other embodiments, one or some of the elongated slots 36 of each of the plurality of alternating ridges 30 may extend or be sized and shaped irregular or differently from other one or some of the elongated slots 36 of the plurality of alternating ridges 30. The size and shape of each elongated slot 36 of each of the plurality of alternating ridges 30 may be dependent on the type of heat-generating device 12, cooling parameters and desires, and the like, as appreciated by those having skill in the art.

Each elongated slot 36 of the plurality of alternating ridges 30 provides a fluid path from the corrugated portion 24 to the cover receiving surface 22a of the base plate 14. That is, the liquid coolant 68 (FIG. 3) may pass though each elongated slot 36 of the plurality of alternating ridges 30 to be fluidly coupled to the cover receiving surface 22a of the base plate 14 to cool the base plate, as discussed in greater detail herein. As such, while each elongated slot 36 of the plurality of alternating ridges 30 provides a direct cooling path for the liquid coolant 68 (FIG. 3) to directly contact the cover receiving surface 22a of the base plate 14, the plurality of alternating valleys 32 provide a barrier against direct fluid contact with the cover receiving surface 22a of the base plate 14. It should be understood that the plurality of alternating valleys 32 may still provide a cooling effect onto the cover receiving surface 22a of the base plate 14 without the need for direct fluid contact. Such an arrangement provides for direct and indirect cooling of the base plate 14 to remove heat generated by the heat-generating device 12, as discussed in greater detail herein.

Still referring to FIGS. 1-3, the insert plate 18 includes an inner surface 38a and an opposite outer surface 38b spaced apart from the inner surface 38a, to define a plate thickness. In some embodiments, the plate thickness may be 0.8 mm. It should be understood that this is non-limiting and the plate thickness may be thinner than 0.8 mm limited only by the material used and the stamping process as appreciated by those with skill in the art, or may be thicker than the 0.8 mm. In the assembled state, portions of the inner surface 38a rest on or abut portions of the corrugated surface 28a of each of the plurality of alternating ridges 30 such that the insert plate 18 is positioned above the macro-channel plate 16 in the vertical direction (e.g., in the +/−Z direction). The insert plate 18 is formed to include a plurality of alternating raised channel portions 40 and the plurality of alternating recesses 42 extending between a pair of terminating ends 44a, 44b and a pair of edges 45a, 45b. The plurality of alternating raised channel portions 40 and the plurality of alternating recesses 42 extend in a second direction, depicted by arrow A2. As such, the plurality of alternating raised channel portions 40 and the plurality of alternating recesses 42 extend generally in the longitudinal direction (e.g., in the +/−X direction) between the pair of terminating ends 44a, 44b. As such, the plurality of alternating raised channel portions 40 and the plurality of alternating recesses 42 extending in the second direction is perpendicular to the plurality of alternating ridges 30 and the plurality of alternating valleys 32 extending in the first direction.

Portions of the inner surface 38a (e.g., at the plurality of alternating recesses 42) may be configured to be generally planar in shape to abut the portions of the corrugated surface 28a of each of the plurality of alternating ridges 30 of the macro-channel plate 16. As such, portions of the inner surface 38a and outer surface 38b alternate to varying heights in the vertical direction (e.g., in the +/−Z direction) to follow the contour of the plurality of alternating raised channel portions 40 and the plurality of alternating recesses 42 formed in the sheet metal stamping process.

In the depicted embodiment, each of the plurality of alternating recesses 42 have a width W3, which is uniform in size and shape to define each of the plurality of alternating recesses 42. Additionally, each of the plurality of alternating raised channel portions 40 have a width W4 and a height H2 with reference to the outer surface 38b of the plurality of alternating recesses 42, which are each uniform in size and shape to define each of the alternating raised channel portions 40. This is non-limiting and each or some of the widths W3 of the plurality of alternating recesses 42 may be irregular or non-uniform width. Further, either independently or in combination with the non-uniform width of the plurality of alternating recesses 42, each width W4 and/or height H2 of the plurality of alternating raised channel portions 40 may be irregular or non-uniform, dependent on the type of heat-generating device 12, cooling parameters and desires, and the like, as appreciated by those having skill in the art.

In some embodiments, as best depicted in FIG. 2, the width W3 of some of the plurality of alternating recesses 42 may be larger, or extend a greater distance, than the width W4 of each of the plurality of alternating raised channel portions 40. This is non-limiting and in some embodiments, the width W3 of one, some, or all of the plurality of alternating recesses 42 may equal to, or extend a same distance, as the width W4 of each of the plurality of alternating raised channel portions 40. In other embodiments, the width W3 of each of the plurality of alternating recesses 42 may be smaller, or extend a less distance, than the width W4 of each of the plurality of alternating raised channel portions 40. Further, in other embodiments, the width W4 of one or some of the plurality of alternating raised channel portions 40 may be larger, or extend a greater distance, than the width W3 of one or some of the plurality of alternating recesses 42.

In the depicted embodiment, each of the plurality of alternating recesses 42 include an elongated passage 46 extending in the same direction as the plurality of alternating recesses 42 (e.g., in the longitudinal direction). In the depicted embodiment, each elongated passage 46 of the plurality of alternating recesses 42 extends between the pair of terminating ends 44a, 44b in the longitudinal direction e.g., in the +/−X direction) and extends a uniform distance D2 or length to be sized and shaped in a uniform geometry. In a non-limiting example, each elongated passage 46 of the plurality of alternating recesses 42 may have a width or opening of 5 mm. It should be understood that this is non-limiting and each elongated passage 46 of the plurality of alternating recesses 42 may have a width or opening greater than or less than 5 mm.

In other embodiments, each elongated passage 46 of the plurality of alternating recesses 42 may extend different distances or lengths, or be sized and/or shaped differently. In other embodiments, one or some of the each elongated passage 46 of the plurality of alternating recesses 42 may extend or be sized and shaped irregular or differently from other elongated passages 46 of the plurality of alternating recesses 42. The size and shape of each elongated passage 46 of each of the plurality of alternating recesses 42 may be dependent on the type of heat-generating device 12, cooling parameters and desires, and the like, as appreciated by those having skill in the art.

Each of the plurality of alternating recesses 42 may include a recess plug 48 that is sized and shaped to be positioned within some or all of the plurality of alternating recesses 42. Each recess plug 48 is sized and shaped to be positioned within a corresponding one of the plurality of alternating recesses 42 in a snap fit configuration to seal off the plurality of alternating recesses 42 at the terminating end 44b. That is, each recess plug 48 may have a width that generally corresponds to the width W3 of the plurality of alternating recesses 42 and may have a height that generally corresponds to the height H2 of the plurality of alternating raised channel portions 40. As such, each recess plug 48 may seal the terminating end 44a to direct the flow of the liquid coolant 68 (FIG. 3) from exiting the insert plate 18 via the terminating end 44a. Rather, the liquid coolant 68 (FIG. 3) is directed back to the elongated passage 46. In other embodiments, each recess plug 48 is positioned within a corresponding one of the plurality of alternating recesses 42 and maintained in position by at least one fastener. Example fasteners may include, without limitation, adhesive, weld, epoxy, rivets, screws, bolt and nut, and/or the like.

Further, each of the plurality of alternating raised channel portions 40 may include a channel plug 50 that is sized and shaped to be positioned within some or all of the plurality of alternating raised channel portions 40. Each channel plug 50 is sized and shaped to be positioned within the plurality of alternating raised channel portions 40 in a snap fit configuration to seal off the plurality of alternating raised channel portions 40 at the terminating end 44b. That is, each channel plug 50 may have a width that generally corresponds to the width W4 of the plurality of alternating raised channel portions 40 and may have a height that generally corresponds to the height H2 of the plurality of alternating raised channel portions 40. As such, each channel plug 50 may seal the terminating end 44b to direct the flow of the liquid coolant 68 (FIG. 3) from exiting the insert plate 18 via the terminating end 44b. In other embodiments, each channel plug 50 is positioned within the plurality of alternating raised channel portions 40 and maintained in position by at least one fastener. Example fasteners may include, without limitation, adhesive, weld, epoxy, rivets, screws, bolt and nut, and/or the like.

Each elongated passage 46 of the plurality of alternating recesses 42 provides a fluid path from the cover plate 20, through the insert plate 18 to the corrugated portion 24 of the macro-channel plate 16. That is, the liquid coolant 68 (FIG. 3) may pass though each elongated passage 46 of the plurality of alternating recesses 42 to be fluidly coupled to the corrugated portion 24 of the macro-channel plate 16, to cool the base plate 14, as discussed in greater detail herein. As such, each elongated passage 46 of the plurality of alternating recesses 42 provides a direct cooling path for the liquid coolant 68 (FIG. 3) to directly contact the corrugated portion 24 of the macro-channel plate 16. It should be understood that the plurality of alternating raised channel portions 40 may still provide a cooling effect onto the corrugated surface 28a of the macro-channel plate 16 without the need for direct fluid contact. Accordingly, such an arrangement provides for direct and indirect cooling of the base plate 14 to remove heat generated by the heat-generating device 12, as discussed in greater detail herein.

Now referring to FIG. 3, each recess plug 48, each channel plug 50, each elongated passage 46 of the plurality of alternating recesses 42, and the plurality of alternating raised channel portions 40 direct the liquid coolant 68 into a plurality of fluid flow paths, such as inlet branches 64 and outlet branches 66 before the liquid coolant 68 enters the plurality of alternating ridges 30 and the plurality of alternating valleys 32 of the macro-channel plate 16 and/or after the liquid coolant 68 exits the plurality of alternating ridges 30 and the plurality of alternating valleys 32 of the macro-channel plate 16. Further, the geometry of the insert plate 18 allows for the liquid coolant 68 of the inlet branches 64 to be positioned along the edges 45a, 45b, as described in greater detail herein.

In some embodiments, the macro-channel plate 16 may be attached or coupled to the insert plate 18 via thermal-mechanical coupling. For example, thermal-mechanical coupling may include, without limitation, braze, weld, epoxy bond, solder, sinter, and/or the like. As such, thermal-mechanical coupling may include any processes to mechanically attach components which may require heat, while other processes to mechanically attach components might not require heat. It should be appreciated that the thermal-mechanical coupling may provide a more monolithic assembly with greater structural rigidity and may establish a thermal conduction heat flow path between the two stamped metal plates (e.g., the insert plate 18 and the macro-channel plate 16). As such, both the insert plate 18 and the macro-channel plate 16 participate in the heat transfer process, which is an improvement from conventional heat sinks where the insert is typically a polymer material.

Referring back to FIGS. 1-3, the cover plate 20 includes an exterior surface 52a and an opposite interior surface 52b. A cavity portion 54 extends from the interior surface 52b towards the exterior surface 52a. The cavity portion 54 is defined by a continuous wall 60 that has a height extending from a flange portion 62 to form a receiving void. The cavity portion 54 is generally illustrated as rectangular in shape. This is non-limiting and the cavity portion 54 may be any shape including, without limitation, square, hexagonal, octagonal, spherical, or any other regular or irregular shape. The cavity portion 54 may generally be sized and shaped to receive the insert plate 18 and at the corrugated portion 24 of the macro-channel plate 16, as discussed in greater detail herein.

As such, the cavity portion 54 may extend a length L1 that, in some embodiments, is as large, or slightly larger, than the corrugated portion 24 and the pair of edges 45a, 45b of the insert plate 18. Further, in some embodiments, the cavity portion 54 may extend a width W5 that is equal to, or slightly larger, than the corrugated portion 24 of the macro-channel plate 16 and the pair of edges 45a, 45b of the insert plate 18. The liquid coolant 68 may flow or travel in the spaces between the interior surface 52b of the continuous wall 60 of the cavity portion 54 and the pair of edges 45a, 45b of the insert plate 18, as best illustrated in FIG. 3. As such, the continuous wall 60 of the cavity portion 54 seals the insert plate 18 and at least the corrugated portion 24 of the macro-channel plate 16 to retain the liquid coolant 68 while directing the liquid coolant 68 through the insert plate 18 and the macro-channel plate 16, as discussed in greater detail herein. In other embodiments, the cavity portion 54 may be sized to further receive the pair of planar tab portions 26 of the macro-channel plate 16.

A fluid inlet aperture 56 and a fluid outlet aperture 58 are positioned within the continuous wall 60 to provide the liquid coolant 68 access to the cavity portion 54 from outside or exterior of the cover plate 20 to the interior space of the cavity portion 54. As such, the fluid inlet aperture 56 and the fluid outlet aperture 58 are each independently fluidly coupled to the cavity portion 54 of the cover plate 20. That is, the liquid coolant 68 may be pumped in or otherwise provided to the fluid inlet aperture 56 to provide fluid within the cavity portion 54 and the fluid outlet aperture 58 may be provided to remove heated liquid coolant from the cavity portion 54.

The flange portion 62 of the cover plate 20 is generally formed to circumferentially surround the continuous wall 60 defining the cavity portion 54. The flange portion 62 may be planar in shape and extend a distance to permit the interior surface 52b to abut with the cover receiving surface 22a along at least the pair of edges 23b. In some embodiments, the interior surface 52b of the cover plate 20 may abut with or otherwise contact the corrugated surface 28a of the pair of planar tab portions 26 on either side of the corrugated portion 24 of the macro-channel plate 16. Accordingly, the cavity portion 54 is configured to receives and fluidly seal the insert plate 18 and at least the corrugated portion 24 of the macro-channel plate 16 and to abut or otherwise be in communication with the base plate 14 such that the cover plate 20, the insert plate 18, the macro-channel plate 16, and the base plate 14 may be in a vertically stacked arrangement (e.g., in the +/−Z direction).

In some embodiments, the cover plate 20, the insert plate 18, the macro-channel plate 16, and the base plate 14 are thermal-mechanically coupled together to make a fluid tight (e.g., leak proof) cold plate assembly with proper flow path and positioned in the vertically stacked arrangement (e.g., in the +/−Z direction). In other embodiments, the cover plate 20 and the base plate 14 are coupled to each other to seal the inserted macro-channel plate 16 and insert plate 18 within and between the cavity portion 54 of the cover plate 20 and the base plate 14. In other embodiments, the insert plate 18 and the macro-channel plate 16 are thermal-mechanically coupled to one another and as an assembly positioned within and between the cavity portion 54 of the cover plate 20 and the base plate 14 in which the cover plate 20 and the base plate 14 are coupled to each other to seal the example cooler assembly 10. As such, it should be appreciated that there are different approaches envisioned to form the vertically stacked arrangement of the example cooler assembly 10.

It should be understood that the vertically stacked arrangement provides for a small or thin total height of the example cooler assembly 10 while providing low manufacturing costs, easily shapeable, scalable, provide for modularity to permit stacking of a plurality of example cooling assemblies, and the like, compared to conventional cold plate cooling assemblies.

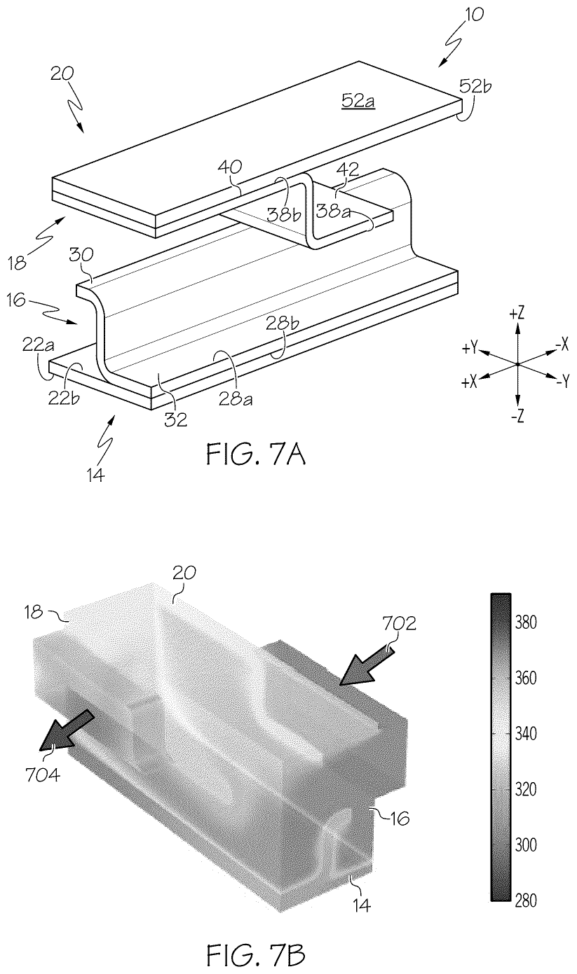

Now referring to FIGS. 7A-7B, the periodic cell geometry is schematically depicted in FIG. 7A and the conjugate heat transfer analysis of the unit cell is schematically depicted in FIG. 7B. As illustrated in FIG. 7A, the thin total height of the example cooler assembly 10 may be minimum in this vertical arrangement. For example, and non-limiting, the height may be 13.6 mm. This is non-limiting and the total height may be more than or less than 13.6 mm. As illustrated, the liquid coolant 68 (FIG. 3) entering the unit cell depicted by arrow 702, cools the unit cell with the warmest portion the base plate 14, and the now warm liquid coolant exits the unit cell, depicted by arrow 704. As such, because of the geometrics and dimensions of the insert plate 18 to create a manifold for the liquid coolant, the unit cell performance may be uniformly extended to the entire area of the base plate 14.

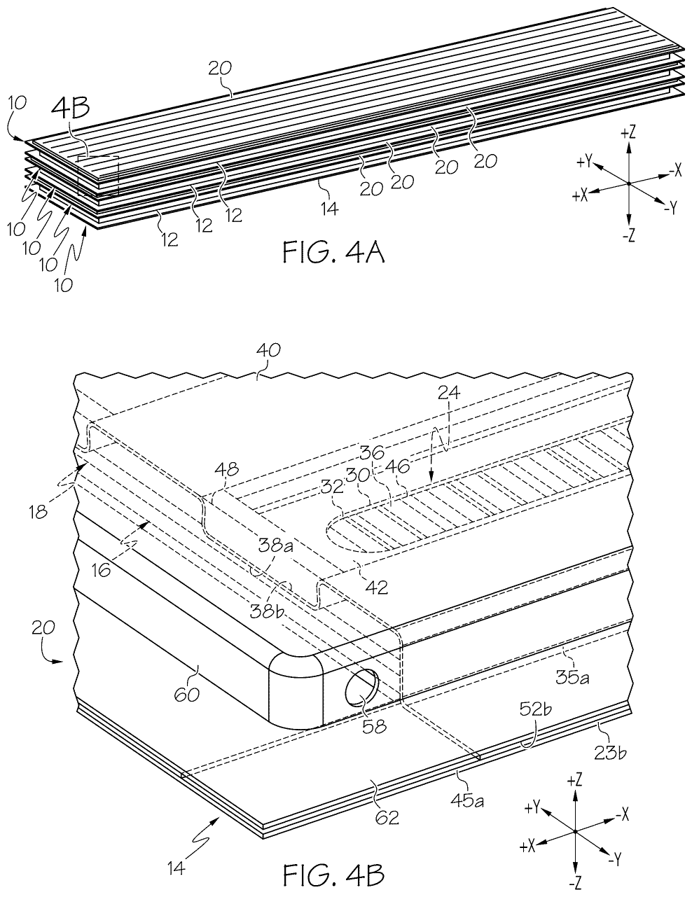

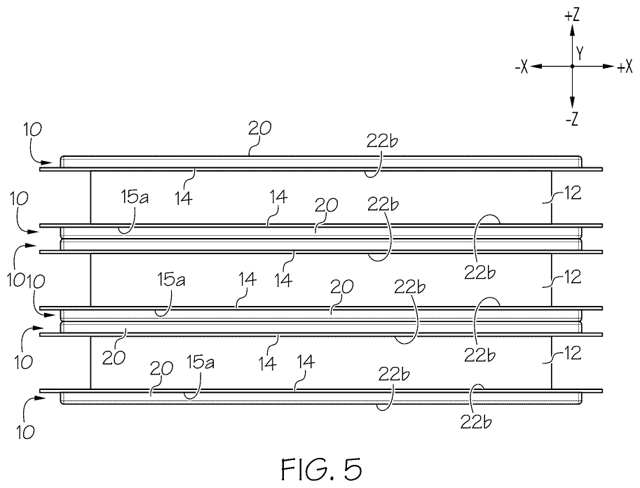

Now referring to FIGS. 4A-4B, and 5-6, a plurality of example cooler assemblies arranged in a stacked configuration to cool a volumetric heat source from both above and below the heat-generating device 12 is schematically depicted. As illustrated, another advantage to the example cooler assembly 10 is that the arrangement of the cold plate assembly 13 permits for modularity to vertically stack a plurality of example cooler assemblies for volumetric cooling above and below, for example, electric vehicle batteries or fuel cell stacks. In some embodiments, two example cooler assemblies may be positioned such that the cover plate 20 of one example cooler assembly 10 abuts the cover plate 20 of another example cooler assembly 10 such that each base plate 14 from both of the example cooler assemblies 10 may be contact with different heat-generating devices 12. Such an arrangement or pattern may continue such that each heat-generating device 12 is cooled on two sides (e.g., the base surface 15a and the contact surface 15b).

In a non-limiting example, the arrangement schematically depicted in FIGS. 4A-4B and 5-6, there are three heat-generating devices 12 depicted, which are cooled by six different and independent example cooler assemblies 10. As such, each example cooler assemblies 10 has its own independent fluid inlet aperture 56, fluid outlet aperture 58 and its own liquid coolant 68 (FIG. 3) within the respective cover plate 20 of the example cooler assembly 10. In some embodiments, each of the example cooler assemblies may be fluidly coupled to one or more pumps, one or more reservoirs, and/or one or more fluid temperature conditioners to supply the liquid coolant, to receive the heated liquid coolant, and to cool the heated liquid coolant, as appreciated by those with skill in the art.

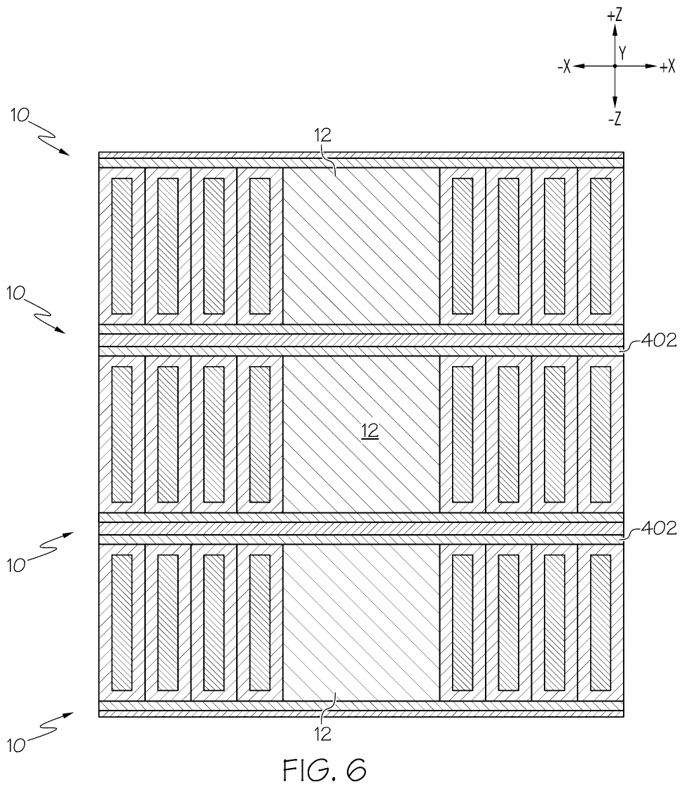

Now referring to FIG. 6, in some embodiments, and electrical insulating layer 402 may be positioned between each example cooler assembly 10. The electrical insulating layer 402 may be laminate also known as pre-preg materials. For example, such materials may include cloth or fiber material combined with a resin material, where the cloth to resin ratio determines a laminate type designation (e.g., FR-4, CEM-1, G-10, etc.) and therefore the characteristics of the laminate produced. A variety of materials having dielectric properties include polytetrafluoroethylene (Teflon), FR-4, FR-1, CEM-1 or CEM-3. Other pre-preg materials that may be used include, without limitation, FR-2 (phenolic cotton paper), FR-3 (cotton paper and epoxy), FR-4 (woven glass and epoxy), FR-5 (woven glass and epoxy), FR-6 (matte glass and polyester), G-10 (woven glass and epoxy), CEM-1 (cotton paper and epoxy), CEM-2 (cotton paper and epoxy), CEM-3 (non-woven glass and epoxy), CEM-4 (woven glass and epoxy), CEM-5 (woven glass and polyester).

As such, the electrical insulating layer 402 electrically isolate the heat-generating device 12 from the example cooler assembly 10 while still providing a thermal coupling between the heat-generating device 12 and the example cooler assembly 10 for the purposes of removing heat generated by the heat-generating device 12.

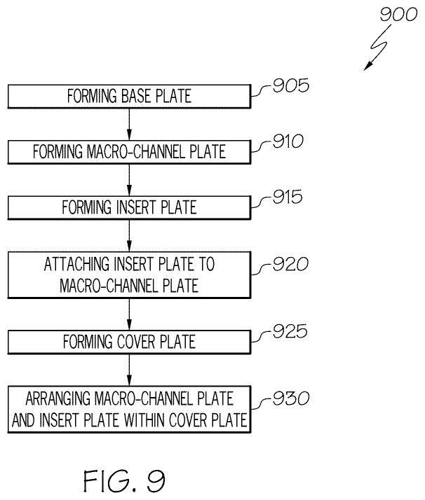

Referring now to FIG. 9, a flow diagram that graphically depicts an illustrative method 900 for forming the example cooler assembly is provided. Although the steps associated with the blocks of FIG. 9 will be described as being separate tasks, in other embodiments, the blocks may be combined or omitted. Further, while the steps associated with the blocks of FIG. 9 will described as being performed in a particular order, in other embodiments, the steps may be performed in a different order.

At block 905, the base plate is formed. The base plate may be formed using sheet metal forming techniques. At block 910, the macro-channel plate is formed. The macro-channel plate may be formed using sheet metal techniques to include the corrugated portion. The size and shape of the corrugated portion may be based on the heat-generating device and the amount of heat desired to be removed. At block 915, the insert plate is formed. The insert plate may be formed using sheet metal techniques to include the plurality of alternating raised channel portions and the plurality of alternating recesses. The size and shape of the plurality of alternating raised channel portions and the plurality of alternating recesses may be based on the heat-generating device and the amount of heat desired to be removed.

At block 920, the insert plate is attached or coupled to the macro-channel plate. The insert plate is attached or coupled to the macro-channel plate via brazing or thermal-mechanical coupling. Such brazing or thermal-mechanical coupling (e.g., welding) may provide a more monolithic assembly with greater structural rigidity and may establish a thermal conduction heat flow path between the two stamped metal plates (e.g., the insert plate and the macro-channel plate). At block 925, the cover plate is formed. The cover plate may be formed using sheet metal techniques and may be formed with a cavity portion configured to receive the insert plate and the macro-channel plate. At block 930, the cover plate is attached or coupled to the base plate to fluidly seal the insert plate and the macro-channel plate within the cavity portion of the cover plate to retain the liquid coolant to direct the liquid coolant between the fluid inlet and fluid outlet, along the branches and through the insert plate and the macro-channel plate, and to form the vertical arrangement of the cold plate assembly.

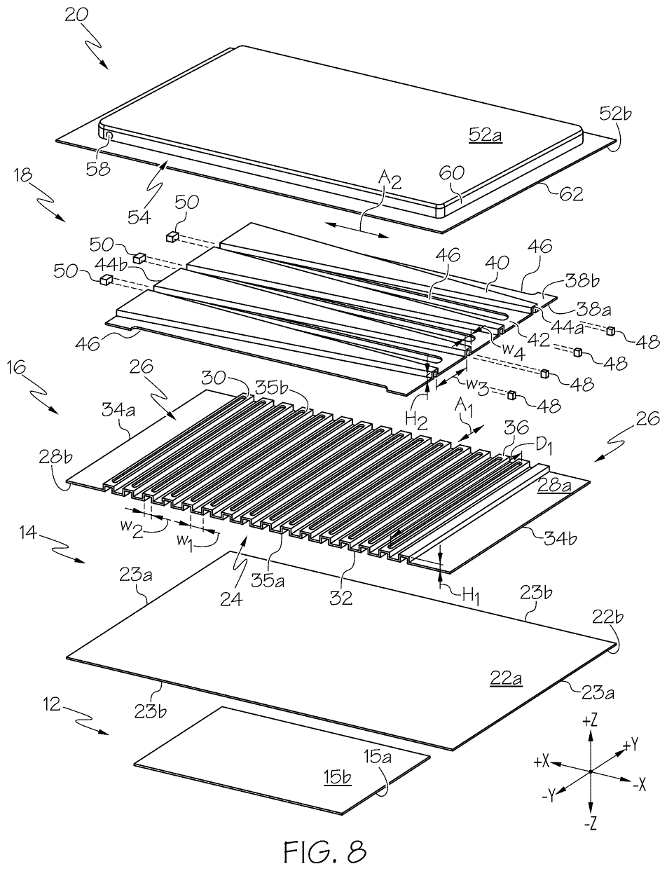

Now referring to FIG. 8, it should be understood that the cooling performance may be adjusted or fine-tuned based on the cooling requirement via changes to the unit cell dimensions and adjusting the flow rate. For example, the geometry of the insert plate 18 and/or cover plate 20 may be changed. As illustrated in FIG. 8, in this embodiment, the cavity portion 54 of the cover plate and the plurality of alternating raised channel portions 40 and the plurality of alternating recesses 42 of the insert plate 18 are each tapered at an angle along a same plane to maximize the flow of the liquid coolant 68. Such geometric changes provide for varying opening sizes for each of the inlet branches 64 and outlet branches 66, as described with respect to FIG. 3 above.

The above-described cooler assembly provides for thermal management of heat-generating devices utilizing four independent stamped sheet metal plates. A stamped macro-channel plate includes a corrugated surface defined by a plurality of alternating ridges and valleys. Each of the plurality of alternating ridges and valleys extend in a first direction. Each of the plurality of alternating ridges include an elongated slot to fluidly couple the macro-channel plate to a base plate. An insert plate includes a plurality of alternating raised channels portions and recesses and includes an elongated passage to fluidly couple the insert plate to the macro-channel plate. Each of the plurality of alternating raised channels portions and recesses extend in a second direction, which is perpendicular to the first direction. Further, the last stamped plate is a cover plate that includes an interior surface with a cavity portion configured to receive and enclose the macro-channel plate and the insert plate. The cooler assembly is in a stacked arrangement in a vertical direction and to seal a liquid coolant inside the cold plate assembly.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A cooler assembly, comprising:
a base plate having a first surface opposite a second surface;
a macro-channel plate having a corrugated portion defined by a plurality of alternating ridges and valleys, each extending in a first direction, each of the plurality of alternating ridges having an elongated slot fluidly coupling the macro-channel plate to the base plate; and
an insert plate having an inner surface and opposite outer surface, the inner surface abutting the plurality of alternating ridges of the macro-channel plate, the insert plate having a plurality of alternating raised channel portions and recesses, each of the plurality of recesses having an elongated passage fluidly coupling the insert plate to the macro-channel plate, each of the plurality of alternating raised channel portions and recesses extending in a second direction that is perpendicular to the first direction.

2. The cooler assembly of claim 1, further comprising:
a cover plate having an interior surface with a cavity portion receiving the macro-channel plate and the insert plate, portions of the interior surface abutting the first surface of the base plate.

3. The cooler assembly of claim 2, wherein the macro-channel plate and the insert plate are received within the cavity portion of the cover plate such that the cooler assembly is in a vertically stacked arrangement.

4. The cooler assembly of claim 2, wherein at least a portion of the cavity portion of the cover plate provides fluid channels to direct a flow of a liquid coolant.

5. The cooler assembly of claim 4, wherein the cavity portion of the cover plate is defined by a continuous wall having a fluid inlet aperture and a fluid outlet aperture.

6. The cooler assembly of claim 1, further comprising:
a heat-generating device coupled to the second surface of the base plate.

7. The cooler assembly of claim 1, further comprising:
at least one plug positioned within at least one of the plurality of recesses to direct a flow of a liquid coolant.

8. The cooler assembly of claim 7, wherein each of the plurality of alternating valleys and the plurality of alternating raised channel portions define a plurality of fluid flow paths for the liquid coolant.

9. The cooler assembly of claim 8, wherein each elongated passage of each of the plurality of recesses receives the liquid coolant from the plurality of fluid flow paths to provide the liquid coolant to the macro-channel plate.

10. The cooler assembly of claim 9, wherein each elongated slot of the plurality of alternating ridges provides the liquid coolant to the base plate to cool the first surface of the base plate.

11. An electronics assembly, comprising:
a heat-generating device; and
a cooler assembly thermally coupled to the heat-generating device, the cooler assembly comprising:
a base plate having a first surface opposite second surface;
a macro-channel plate having a corrugated portion defined by a plurality of alternating ridges and valleys, each extending in a first direction, each of the plurality of alternating ridges having an elongated slot to fluidly coupling the macro-channel plate to the base plate; and
an insert plate having an inner surface and opposite outer surface, the inner surface abutting the plurality of alternating ridges of the macro-channel plate, the insert plate having a plurality of alternating raised channel portions and recesses, each of the plurality of recesses having an elongated passage fluidly coupling the insert plate to the macro-channel plate, each of the plurality of alternating raised channel portions and recesses extending in a second direction that is perpendicular to the first direction; and
a cover plate having an interior surface with a cavity portion configured to receive the macro-channel plate and the insert plate, portions of the interior surface abutting the first surface of the base plate,
wherein the heat-generating device is thermally coupled to the second surface of the base plate.

12. The electronics assembly of claim 11, wherein at least a portion of the cavity portion of the cover plate provides fluid channels to direct a flow of a liquid coolant.

13. The electronics assembly of claim 12, wherein the cavity portion of the cover plate has a fluid inlet aperture and a fluid outlet aperture.

14. The electronics assembly of claim 11, further comprising:
at least one plug configured to be positioned within at least one of the plurality of recesses to direct a flow of a liquid coolant.

15. The electronics assembly of claim 14, wherein each of the plurality of alternating valleys and the plurality of alternating raised channel portions define a plurality of fluid flow paths for the liquid coolant.

16. The electronics assembly of claim 15, wherein each of the elongated passage of each of the plurality of recesses receive the liquid coolant from the plurality of fluid flow paths to provide the liquid coolant to the macro-channel plate.

17. The electronics assembly of claim 16, wherein each of the elongated slot of the plurality of alternating ridges provides the liquid coolant to the base plate to cool the first surface of the base plate.

18. The electronics assembly of claim 11, wherein the macro-channel plate and the insert plate are received within the cavity portion of the cover plate such that the cooler assembly is in a vertically stacked arrangement.

19. A method for forming a cooler assembly, the method comprising:
forming a base plate having a first surface and an opposite second surface defining a thickness;
forming a macro-channel plate having a plurality of alternating ridges and a plurality of alternating valleys extending in a first direction, each of the plurality of alternating ridges having an elongated slot configured to fluidly couple the macro-channel plate to the first surface of the base plate;
forming an insert plate having a plurality of alternating raised channel portions and a plurality of alternating recesses, each of the plurality of alternating raised channel portions and each of the plurality of alternating recesses extending in a second direction, the second direction is perpendicular to the first direction, each of the plurality of alternating recesses having an elongated passage configured to fluidly couple the insert plate to the macro-channel plate; and
forming a cover plate having a cavity portion configured to receive the insert plate and the macro-channel plate, portions of the cover plate is configured to abut with the first surface of the base plate in an assembled state such that the cooler assembly is in a vertically stacked arrangement.

20. The method of claim 19, further comprising:
coupling the insert plate to the macro-channel plate via a thermal-mechanical coupling.
